(19) United States
(12) Patent Application Publication
(10) Pub. No.: US 2024/0140816 A1
(43) Pub. Date: May 2, 2024

(54) GALLIA PARTICLES AND METHOD FOR PRODUCING GALLIA PARTICLES

(71) Applicant: DIC Corporation, Tokyo (JP)

(72) Inventors: Shaowei YANG, Qingdao, Shandong (CN); Minoru TABUCHI, Chiba (JP); Jianjun YUAN, Sakura-shi (JP); Wei ZHAO, Qingdao, Shandong (CN); Jian GUO, Shandong (CN)

(73) Assignee: DIC Corporation, Tokyo (JP)

(21) Appl. No.: 18/567,348

(22) PCT Filed: Jun. 11, 2021
(86) PCT No.: PCT/CN2021/099882

§ 371 Date: Dec. 5, 2023

(51) Int. Cl. C01G 15/00

(52) U.S. Cl. CPC C01G 15/00; C01P 2002/08; C01P 2002/72; C01P 2002/85; C01P 2004/03; C01P 2004/61; C01P 2004/62; C01P 2004/82

(57) ABSTRACT

Gallia particles containing molybdenum. A method for producing the gallia particles, including calcining a gallium compound in the presence of a molybdenum compound.

### TECHNICAL FIELD

The present invention relates to gallia particles and a method for producing the gallia particles.

### BACKGROUND

Gallium oxide (that is, gallia) has been used and studied in a wide range of applications such as lasers and phosphors, light emitting materials, catalysts, insulating barrier materials for semiconductor junctions, gas sensors, dielectric coatings for solar cells, and materials for next-generation power devices.

For example, PTL 1 discloses that powders including fine particles of gallium or of a gallium alloy having a melting point of 150° C. or lower, which are low melting point metal powders in which a hydroxide and/or an oxide film is formed on a surface of the fine particles, were heated at 1000° C. for one hour in the air using an electric furnace to produce gallium oxide (Ga₂O₃).

### CITATION LIST

### Patent Literature

PTL 1: JP-A-2010-236009

### SUMMARY

### Technical Problem

However, knowledge about conventional gallia particles and a method for producing the gallia particles is limited, and there is still room for study.

Therefore, an object of the present invention is to provide gallia particles having excellent properties and a method for producing the gallia particles.

### Solution to Problem

The present invention includes the following aspects.
[1] Gallia particles containing molybdenum.
[2] The gallia particles according to [1] above, in which the molybdenum is unevenly distributed in a surface layer of the gallia particles.
[3] The gallia particles according to [1] or [2] above, in which a median diameter D50 of the gallia particles calculated by a laser diffraction/scattering method is 0.1 to 1000 μm.
[4] The gallia particles according to any one of [1] to [3] above, in which Ga₂O₃ content (G₁) with respect to 100 mass % of the gallia particles determined by XRF analysis of the gallia particles is 65 to 99.95 mass %, and MoO₃ content (M₁) with respect to 100 mass % of the gallia particles determined by XRF analysis of the gallia particles is 0.05 to 20 mass %.
[5] The gallia particles according to any one of [1] to [4] above, in which Ga₂O₃ content (G₂) with respect to 100 mass % of a surface layer of the gallia particles determined by XPS surface analysis of the gallia particles is 10 to 98 mass %, and MoO₃ content (M₂) with respect to 100 mass % of the surface layer of the gallia particles determined by XPS surface analysis of the gallia particles is 2 to 40 mass %.
[6] The gallia particles according to any one of [1] to [5] above, in which a surface layer uneven distribution ratio (M₂/M₁) of MoO₃ content (M₂) with respect to 100 mass % of a surface layer of the gallia particles determined by XPS surface analysis of the gallia particles to MoO₃ content (M₁) with respect to 100 mass % of the gallia particles determined by XRF analysis of the gallia particles is 2 to 80.
[7] A method for producing the gallia particles according to any one of [1] to [6] above, including calcining a gallium compound in presence of a molybdenum compound.
[8] The method for producing the gallia particles according to [7] above, in which the molybdenum compound is at least one compound selected from a group including molybdenum trioxide, lithium molybdate, potassium molybdate and sodium molybdate.
[9] The method for producing the gallia particles according to [7] or [8] above, in which a calcination temperature for the calcining is 800 to 1600° C.

### Advantageous Effects of Invention

According to the present invention, it is possible to provide the gallia particles having excellent properties and a method for producing the gallia particles.

### BRIEF DESCRIPTION OF DRAWINGS

FIG. 1 is an SEM photograph of gallia particles of Example 1.

FIG. 2 is the SEM photograph of the gallia particles of Example 2.

FIG. 3 is the SEM photograph of the gallia particles of Example 3.

FIG. 4 is the SEM photograph of the gallia particles of Example 5.

FIG. 5 is the SEM photograph of the gallia particles of Comparative Example 1.

FIG. 6 is the SEM photograph of the gallia particles of Comparative Example 2.

FIG. 7 is a graph illustrating results of XRD measurement of the gallia particles of Examples and Comparative Examples.

### DESCRIPTION OF EMBODIMENTS

Hereinafter, an embodiment of gallia particles and a method for producing the gallia particles of the present invention will be described.

<<Gallia Particles>>

The gallia particles of the embodiment contain molybdenum. The gallia particles of the embodiment contain molybdenum and have excellent properties such as catalytic activity and shape derived from molybdenum.

In the gallia particles of the embodiment, the molybdenum is preferably unevenly distributed in a surface layer of the gallia particles.

Here, the “surface layer” in this specification means within 10 nm from a surface of the gallia particles of the embodiment. This distance corresponds to a detection depth of XPS used for measurement in Examples.

Here, “unevenly distributed in the surface layer” means that a mass of molybdenum or the molybdenum compound per unit volume in the surface layer is greater than that of molybdenum or the molybdenum compound per unit volume in other than the surface layer.

In the gallia particles of the embodiment, the fact that molybdenum is unevenly distributed in the surface layer of the gallia particles is confirmed by the fact that MoO₃ content (M₂) with respect to 100 mass % of the surface layer of the gallia particles determined by XPS surface analysis of the gallia particles is greater than MoO₃ content (M₁) with respect to 100 mass % of the gallia particles determined by XRF (fluorescent X-ray) analysis of the gallia particles as described in Examples described below.

In the gallia particles of the embodiment, as an index that molybdenum is unevenly distributed in the surface layer of the gallia particles, a surface layer uneven distribution ratio (M₂/M₁) of the MoO₃ content (M₂) to the MoO₃ content (M₁) of the gallia particles of the embodiment is preferably 2 to 80, more preferably 3 to 60, even more preferably 5 to 50.

By unevenly distributing molybdenum or the molybdenum compound in the surface layer, excellent properties such as catalytic activity can be efficiently imparted as compared with a case where molybdenum or the molybdenum compound is uniformly present not only in the surface layer but also in other than the surface layer (inner layer).

The gallia particles of the embodiment produced by a production method of the embodiment can have a unique granular or columnar shape as described in Examples described below.

In this specification, “columnar shape” includes a prismatic shape, a columnar shape, a rod shape, and the like. A shape of a bottom surface of a columnar body of columnar gallia particles is not particularly limited, and examples thereof include a circular shape, an elliptical shape, and a polygonal shape. The columnar body includes a body that extends straight in a length direction thereof, a body that extends in an inclined manner, a body that extends while bending, a shape that branches in a branch shape, and the like.

In the gallia particles of the embodiment, a particle size and molybdenum content of gallia particles obtained can be controlled by controlling a used amount and type of the molybdenum compound in the production method described below.

A median diameter D₅₀ of the gallia particles of the embodiment calculated by a laser diffraction/scattering method is preferably 0.1 to 1000 μm, preferably 0.3 to 100 μm, more preferably 0.5 to 30 μm, and even more preferably 0.7 to 15 μm.

The median diameter D₅₀ of a sample of the gallia particles calculated by the laser diffraction/scattering method can be determined as a particle diameter in which a ratio of cumulative volume % is 50% in a particle diameter distribution measured by a dry method using a laser diffraction type particle size distribution meter.

A particle diameter D₁₀ of the gallia particles of the embodiment calculated by the laser diffraction/scattering method is preferably 0.05 to 100 μm, more preferably 0.08 to 50 μm, and even more preferably 0.1 to 10 μm.

The particle diameter D₁₀ of the sample of the gallia particles calculated by the laser diffraction/scattering method can be determined as a particle diameter in which the ratio of cumulative volume % from a small particle side is 10% in the particle diameter distribution measured by the dry method using the laser diffraction type particle size distribution meter.

A particle diameter D₉₀ of the gallia particles of the embodiment calculated by the laser diffraction/scattering method is preferably 1.5 to 1500.00 μm, more preferably 1.8 to 100 μm, and even more preferably 2.0 to 50 μm.

The particle diameter D₉₀ of the sample of the gallia particles calculated by the laser diffraction/scattering method can be determined as a particle diameter in which the ratio of cumulative volume % from the small particle side is 90% in the particle diameter distribution measured by the dry method using the laser diffraction type particle size distribution meter.

The gallia particles of the embodiment contain gallium oxide (that is gallia). Examples of gallium oxide that the gallia particles of the embodiment may contain include Ga₂O₃.

The gallia particles of the embodiment preferably contain 65 to 99.95 mass %, more preferably 70 to 99.5 mass %, and even more preferably 90 to 99 mass % of Ga₂O₃ with respect to 100 mass % of the gallia particles.

Gallia content in the gallia particles can be measured by XRF analysis. In the gallia particles of the embodiment, Ga₂O₃ content (G₁) with respect to 100 mass % of the gallia particles determined by XRF analysis of the gallia particles is preferably 65 to 99.95 mass %, more preferably 70 to 99.5 mass %, and even more preferably 90 to 99 mass %.

The gallia particles of the embodiment contain molybdenum. In the gallia particles of the embodiment, the MoO₃ content (M₁) with respect to 100 mass % of the gallia particles determined by XRF analysis of the gallia particles is preferably 0.05 to 20 mass %, more preferably 0.08 to 15 mass %, more preferably 0.09 to 10 mass %, and even more preferably 0.1 to 5 mass %.

Upper limit values and lower limit values of the Ga₂O₃ content (G₁) and the MoO₃ content M₁ exemplified above in the gallia particles of the embodiment can be freely combined. Further, numerical values of the Ga₂O₃ content (G₁) and the MoO₃ content (M₁) can be freely combined.

As an example of the gallia particles of the embodiment, the gallia particles having the Ga₂O₃ content (G₁) of 65 to 99.95 mass %, and the MoO₃ content (M₁) of 0.05 to 20 mass % can be exemplified.

The Ga₂O₃ content (G₁) and the MoO₃ content (M₁) can be measured by XRF analysis, for example, using a fluorescent X-ray analyzer (PrimusIV) manufactured by Rigaku Corporation.

The gallia content contained in the surface layer of the gallia particles can be measured by X-ray photoelectron spectroscopy (XPS) surface analysis. In the gallia particles of the embodiment, Ga₂O₃ content (G₂) with respect to 100 mass % of the surface layer of the gallia particles determined by XPS surface analysis of the gallia particles is preferably 10 to 98 mass %, more preferably 20 to 80 mass %, and even more preferably 30 to 70 mass %.

In the gallia particles of the embodiment, the MoO₃ content (M₂) with respect to 100 mass % of the surface layer of the gallia particles determined by XPS surface analysis of the gallia particles is preferably 2 to 40 mass %, more preferably 3 to 35 mass %, and even more preferably 4 to 20 mass %.

Upper limit values and lower limit values of the Ga₂O₃ content (G₂) and the MoO₃ content (M₂) exemplified above in the gallia particles of the embodiment can be freely combined. Further, numerical values of the Ga₂O₃ content (G₂) and the MoO₃ content (M₂) can be freely combined.

As an example of the gallia particles of the embodiment, the gallia particles having the Ga₂O₃ content (G₂) of 10 to 98 mass %, and the MoO₃ content (M₂) of 2 to 40 mass % can be exemplified.

The above Ga₂O₃ content (G₂) refers to a value determined as the content of Ga₂O₃ with respect to 100 mass % of the surface layer of the gallia particles by obtaining an abundance ratio (atom %) for each element by XPS surface analysis of the gallia particles by X-ray photoelectron spectroscopy (XPS) and by converting the gallium content to oxide.

The above MoO₃ content (M₂) refers to a value determined as the content of MoO₃ with respect to 100 mass % of the surface layer of the gallia particles by obtaining an abundance ratio (atom %) for each element by XPS surface analysis of the gallia particles by X-ray photoelectron spectroscopy (XPS) and by converting the molybdenum content to oxide.

The gallia particles of the embodiment may further contain lithium, potassium, or sodium in addition to molybdenum.

<Method for Producing Gallia Particles>

The method for producing the gallia particles of the embodiment includes a step of calcining a gallium compound in presence of the molybdenum compound. More specifically, the production method of the embodiment is the method for producing the gallia particles, which may include mixing the gallium compound and the molybdenum compound to form a mixture, and calcining the mixture.

According to the method for producing the gallia particles of the embodiment, the gallia particles of the embodiment described above can be produced.

A preferred method for producing the gallia particles includes a step (mixing step) of mixing the gallium compound and the molybdenum compound to form the mixture, and a step (calcination step) of calcining the mixture.

[Mixing Step]

The mixing step is a step of mixing the gallium compound and the molybdenum compound to form the mixture. The contents of the mixture will be described below.

(Gallium Compound)

The gallium compound is not limited as long as it is a compound that can be calcined to be the gallium oxide (that is gallia). Examples of the gallium compound include the gallium oxide, gallium hydroxide, and the gallium oxide is preferable. The gallium oxide may be Ga₂O₃, Ga₂O, or gallium oxide including Ga₂O₃ and Ga₂O.

Since a shape of the gallia particles after calcination hardly reflects a shape of a raw material gallium compound, any shape such as a sphere, an amorphous shape, a structure having an aspect (a wire, a fiber, a ribbon, a tube, or the like), or a sheet can be suitably used as the gallium compound.

(Molybdenum Compound)

Examples of the molybdenum compound include molybdenum oxide and molybdate compounds.

Examples of the molybdenum oxide include molybdenum dioxide and molybdenum trioxide, and the molybdenum trioxide is preferable.

The molybdate compound is not limited as long as it is a salt compound of molybdenum oxoanion such as MoO₄²—, Mo₂O₇²—, Mo₃O₁₀²—, Mo₄O₁₃²—, Mo₅O₁₆²—, Mo₆O₁₉²—, Mo₇O₂₄⁶—, or MoO₂₆⁴—. It may be an alkali metal salt of the molybdenum oxoanion, an alkaline earth metal salt, or an ammonium salt.

As the molybdate compound, the alkali metal salt of the molybdenum oxoanion is preferable, lithium molybdate, potassium molybdate or sodium molybdate is more preferable, and potassium molybdate or sodium molybdate is further preferable.

In the method for producing the gallia particles of the embodiment, the molybdate compound may be a hydrate.

The molybdate compound is preferably at least one compound selected from a group including molybdenum trioxide, lithium molybdate, potassium molybdate, and sodium molybdate, and more preferably at least one compound selected from a group including molybdenum trioxide, potassium molybdate, and sodium molybdate.

The method for producing the gallia particles of the embodiment may include a step of calcining the gallium compound in the presence of the molybdenum compound and a potassium compound.

The method for producing the gallia particles of the embodiment can include the step (mixing step) of mixing the gallium compound, the molybdenum compound, and the potassium compound to form the mixture prior to the calcination step, and can include the step (calcination step) of calcining the mixture.

The method for producing the gallia particles of the embodiment can include the step (mixing step) of mixing the gallium compound and a compound containing molybdenum and potassium to form the mixture prior to the calcination step, and can include the step (calcination step) of calcining the mixture.

The compound containing molybdenum and potassium, which is suitable as a flux agent, can be produced, for example, using a molybdenum compound and a potassium compound, which are cheaper and more easily available, as raw materials in the calcination step. Here, both when the molybdenum compound and the potassium compound are used as the flux agent and when the compound containing molybdenum and potassium is used as the flux agent are combined and regarded as when the molybdenum compound and the potassium compound are used as the flux agent, that is, in the presence of the molybdenum compound and the potassium compound.

The method for producing the gallia particles of the embodiment may include a step of calcining the gallium compound in the presence of the molybdenum compound and a sodium compound.

The method for producing the gallia particles of the embodiment can include a step (mixing step) of mixing the gallium compound, the molybdenum compound, and the sodium compound to form the mixture prior to the calcination step, and can include a step (calcination step) of calcining the mixture.

Alternatively, the method for producing the gallia particles of the embodiment can include a step (mixing step) of mixing the gallium compound and a compound containing molybdenum and sodium to form the mixture prior to the calcination step, and can include a step (calcination step) of calcining the mixture.

The compound containing molybdenum and sodium, which is suitable as the flux agent, can be produced, for example, using the molybdenum compound and the sodium compound, which are cheaper and more easily available, as raw materials in the calcination step. Here, both when the molybdenum compound and the sodium compound are used as the flux agent and when the compound containing molybdenum and sodium is used as the flux agent are combined and regarded as when the molybdenum compound and the sodium compound are used as the flux agent, that is, in the presence of the molybdenum compound and the sodium compound.

By calcining the gallium compound in the presence of the molybdenum compound and the potassium compound, or in the presence of the molybdenum compound and the sodium compound, the gallia particles having a high molybdenum content can be easily obtained, and the particle diameter of the gallia particles produced can be easily adjusted. The reason is not clear, but the following reasons can be considered. For example, since K₂MoO₄ and Na₂MoO₄ are stable compounds and are difficult to volatilize in the calcination step, they are unlikely to be accompanied by a rapid reaction in a volatilization step, and growth of the gallia particles can be easily controlled. Further, it is considered that the molten K₂MoO₄ and Na₂MoO₄ exert a function like a solvent, and for example, by increasing a reaction time, a value of the particle diameter can be increased.

In the method for producing the gallia particles of the embodiment, the molybdenum compound is used as the flux agent. Hereinafter, in this specification, the production method using the molybdenum compound as the flux agent may be simply referred to as the “flux method”. Note that after the molybdenum compound reacts with the gallium compound at a high temperature to form gallium molybdate by such calcination, when the gallium molybdate is further decomposed into gallium and molybdenum oxide at a higher temperature, it is considered that the molybdenum compound is incorporated into the gallia particles. It is considered that the molybdenum oxide is sublimated and removed from the system, and in this step, the molybdenum compound and the gallium compound react to form the molybdenum compound in the surface layer of the gallia particles. Regarding formation mechanism of the molybdenum compound contained in the gallia particles, more specifically, it is considered that Mo—O—Ga is formed in the surface layer of the gallia particles by reaction of molybdenum and Ga atoms, Mo is desorbed by high-temperature calcination, and the molybdenum oxide, a compound having a Mo—O—Ga bond, or the like is formed in the surface layer of the gallia particles.

The molybdenum oxide that is not incorporated into the gallia particles can also be recovered by sublimation and reused. In this way, an amount of the molybdenum oxide adhering to the surface of the gallia particles can be reduced, and original properties of the gallia particles can be maximized.

On the other hand, the alkali metal salt of the molybdenum oxoanion does not vaporize even in a calcination temperature range and can be easily recovered by washing after calcination, so that an amount of the molybdenum compound released to outside a calcining furnace is also reduced, and production cost can also be significantly reduced.

In the above flux method, for example, when the molybdenum compound and the potassium compound are used in combination, it is considered that the molybdenum compound and the potassium compound first react to form the potassium molybdate. At the same time, it is considered that the molybdenum compound reacts with the gallium compound to form the gallium molybdate. Then, for example, it is considered that the gallium molybdate is decomposed in the presence of potassium molybdate in a liquid phase to grow crystals, so that the gallia particles having a large particle size and a high molybdenum content can be easily obtained while suppressing evaporation of flux (sublimation of MoO₃) described above.

(Metal Compound)

A metal compound can be used at a time of calcination if desired. The method for producing the gallia particles of the embodiment can include a step (mixing step) of mixing the gallium compound, the molybdenum compound, the potassium compound, and the metal compound to form the mixture prior to the calcination step, and can include a step (calcination step) of calcining the mixture.

The metal compound is not particularly limited, but preferably contains at least one selected from a group including Group II metal compounds and Group III metal compounds.

Examples of the Group II metal compounds include magnesium compounds, calcium compounds, strontium compounds, barium compounds and the like.

Examples of the Group III metal compounds include scandium compounds, yttrium compounds, lanthanum compounds, cerium compounds and the like.

Note that the above-mentioned metal compound means an oxide, a hydroxide, a carbonate, or a chloride of a metal element. For example, in the case of the yttrium compound, yttrium oxide (Y₂O₃), yttrium hydroxide, and yttrium carbonate can be mentioned. Of these, the metal compound is preferably an oxide of the metal element. Note that the metal compound contains an isomer.

Of these, the metal compound of period 3 element, the metal compound of period 4 element, the metal compound of period 5 element, and the metal compound of period 6 element are preferable, the metal compound of period 4 element and the metal compound of period 5 element are more preferable, and the metal compound of period 5 element is further preferable. Specifically, the magnesium compound, the calcium compound, the yttrium compound, and the lanthanum compound are preferably used, the magnesium compound, the calcium compound, and the yttrium compound are more preferably used, and the yttrium compound is particularly preferably used.

The metal compound is preferably used in a proportion of, for example, 0 to 1.2 mass % (for example, 0 to 1 mol %) with respect to a total amount of the gallium compounds used in the mixing step.

In the method for producing the gallia particles of the embodiment, blending amounts of the gallium compound and the molybdenum compound are not particularly limited, but preferably 35 mass % or more of the gallium compound and 65 mass % or less of the molybdenum compound are mixed with respect to 100 mass % of the mixture to form the mixture, and the mixture can be calcined. More preferably, 40 mass % or more and 99 mass % or less of the gallium compound and 0.5 mass % or more and 60 mass % or less of the molybdenum compound are mixed with respect to 100 mass % of the mixture to form the mixture, and the mixture can be calcined. Even more preferably, 50 mass % or more and 90 mass % or less of the gallium compound and 2 mass % or more and 50 mass % or less of the molybdenum compound are mixed with respect to 100 mass % of the mixture to form the mixture, and the mixture can be calcined.

In the method for producing the gallia particles of the embodiment, a value of a molar ratio (molybdenum/gallium) of molybdenum atom in the molybdenum compound and gallium atom in the gallium compound is preferably 0.01 or more, more preferably 0.03 or more, even more preferably 0.04 or more, and particularly preferably 0.05 or more.

An upper limit value of the molar ratio of the molybdenum atom in the molybdenum compound and the gallium atom in the gallium compound may be appropriately determined, but from a viewpoint of reducing the amount of molybdenum compound used and improving production efficiency, for example, the value of the above molar ratio (molybdenum/gallium) may be 5 or less, 3 or less, 1 or less, or 0.5 or less.

As an example of a numerical range of the molar ratio (molybdenum/gallium), for example, the value of molybdenum/gallium may be 0.01 to 5, 0.03 to 3, 0.04 to 1, and 0.05 to 0.5.

It should be noted that as the amount of molybdenum used with respect to the gallium is increased, the gallia particles having a large particle size shown in the above particle size distribution tend to be obtained.

By using various compounds in the above range, the amount of the molybdenum compound contained in the gallia particles obtained becomes more appropriate, and the gallia particles having a controlled particle size can be easily obtained.

[Calcination Step]

The calcination step is a step of calcining the mixture. The gallia particles according to the embodiment can be obtained by calcining the mixture. As described above, the production method is called the flux method.

The flux method is classified as a solution method. More specifically, the flux method is a method of crystal growth utilizing the fact that a crystal-flux two-component phase diagram shows a eutectic type. A mechanism of the flux method is presumed to be as follows. That is, when a mixture of solute and the flux is heated, the solute and the flux become a liquid phase. At this time, since the flux is a fusing agent, in other words, since a solute-flux two-component phase diagram shows a eutectic type, the solute melts at a temperature lower than its melting point to form the liquid phase. If the flux is evaporated in this state, concentration of the flux is reduced, in other words, an effect on lowering the melting point of the solute by the flux is reduced, and the evaporation of the flux acts as a driving force to cause crystal growth of the solute (flux evaporation method). Note that the solute and the flux can also cause the crystal growth of the solute by cooling the liquid phase (slow cooling method).

The flux method has merits such as being able to grow the crystals at a temperature much lower than the melting point, being able to precisely control a crystal structure, and being able to form a crystalline body having an automorphic shape.

In production of the gallia particles by the flux method using the molybdenum compound as the flux, the mechanism is not always clear, but for example, it is presumed that the mechanism is as follows. That is, when the gallium compound is calcined in the presence of the molybdenum compound, the gallium molybdate is first formed. At this time, as can be understood from the above description, the gallium molybdate grows gallia crystals at a temperature lower than the melting point of the gallia. Then, for example, by evaporating the flux, the gallium molybdate is decomposed to grow the crystals, so that the gallia particles can be obtained. That is, the molybdenum compound functions as the flux, and the gallia particles are produced via an intermediate called the gallium molybdate.

By the above flux method, the gallia particles containing molybdenum and in which the molybdenum is unevenly distributed in the surface layer of the gallia particles can be produced.

A method of calcination is not particularly limited, and the calcination can be performed by a known and commonly used method. When the calcination temperature exceeds 800° C., it is considered that the gallium compound and the molybdenum compound react to form the gallium molybdate. Further, it is considered that when the calcination temperature becomes 950° C. or higher, the gallium molybdate is decomposed to form the gallia particles. Further, in the gallia particles, it is considered that the molybdenum compound is incorporated into the gallia particles when the gallium molybdate is decomposed into the gallia and the molybdenum oxide.

Further, a state of the gallium compound and the molybdenum compound at the time of calcination is not particularly limited, and the molybdenum compound may be present in the same space where the molybdenum compound can act on the gallium compound. Specifically, the state may be simple mixing in which powders of the molybdenum compound and powders of the gallium compound are mixed, mechanical mixing using a crusher or the like, a mixture using a mortar or the like, and may be mixing in a dry state or in a wet state.

Conditions of the calcination temperature are not particularly limited, and are appropriately determined in consideration of a target particle size of the gallia particles, formation of the molybdenum compound in the gallia particles, the shape of the gallia particles, and the like. The calcination temperature may be 900° C. or higher, which is close to a decomposition temperature of the gallium molybdate, 950° C. or higher, or 1000° C. or higher.

As the calcination temperature is higher, the gallia particles having a controlled particle shape and a large particle size tend to be easily obtained. From a viewpoint of efficiently producing such gallia particles, the calcination temperature is preferably 950° C. or higher, more preferably 1000° C. or higher, even more preferably 1100° C. or higher, and particularly preferably 1200° C. or higher.

Generally, when trying to control the shape of the gallia particles obtained after calcination, it is necessary to perform the high-temperature calcination at a temperature of over 1900° C., which is close to the melting point of the gallia, but there is a big problem in industrial applications from viewpoints of load on the calcining furnace and fuel cost.

According to the embodiment of the present invention, for example, even if the maximum calcination temperature for calcining the gallium compound is 1600° C. or lower, the gallia particles can be efficiently formed at low cost.

Further, according to the method for producing the gallia particles of the embodiment, even if the calcination temperature is 1600° C. or lower, which is much lower than the melting point of the gallia, the gallia particles having an automorphic shape can be formed regardless of a shape of a precursor. From this point of view, the calcination temperature is preferably 1500° C. or lower, more preferably 1400° C. or lower, even more preferably 1300° C. or lower, and particularly preferably 1200° C. or lower.

As an example, a numerical range of the calcination temperature at which the gallium compound is calcined in the calcination step may be 900° C. to 1600° C., 900° C. to 1500° C., 950° C. to 1400° C., 1000° C. to 1300° C., or 1000° C. to 1200° C.

From a viewpoint of the production efficiency, a heating rate may be 20° C./hour to 600° C./hour, 40° C./hour to 500° C./hour, and 80° C./hour to 400° C./hour.

Regarding a calcination time, the calcination is preferably performed such that a raising time to a predetermined calcination temperature is in a range of 15 minutes to 10 hours. A holding time at the calcination temperature can be 5 minutes or more, preferably in the range of 5 minutes to 1000 hours, and more preferably in the range of 1 to 30 hours. In order to efficiently form the gallia particles, the holding time at the calcination temperature of 2 hours or more is more preferable, and the holding time at the calcination temperature of 2 to 24 hours is particularly preferable.

As an example, by selecting the conditions of the calcination temperature of 900° C. to 1600° C. and the holding time at the calcination temperature of 2 to 24 hours, the gallia particles of the embodiment containing molybdenum can be easily obtained.

Calcination atmosphere is not particularly limited as long as an effect of the present invention can be obtained, but for example, oxygen-containing atmosphere such as air or oxygen or an inert atmosphere such as nitrogen, argon or carbon dioxide is preferable, and air atmosphere is more preferable when considering the cost.

An apparatus for calcination is also not necessarily limited, and a so-called calcining furnace can be used. The calcining furnace is preferably made of a material that does not react with sublimated molybdenum oxide, and it is preferable to use a highly airtight calcining furnace so that the molybdenum oxide can be used efficiently.

[Molybdenum Removal Step]

The method for producing the gallia particles of the embodiment may further include a molybdenum removal step of removing at least a part of molybdenum after the calcination step, if necessary.

As described above, since the molybdenum is sublimated during calcination, it is possible to control the molybdenum content present in the surface layer of the gallia particles, and to control the molybdenum content and its existence state in other than the surface layer (inner layer) of the gallia particles, by controlling the calcination time, the calcination temperature, and the like.

The molybdenum can adhere to the surface of the gallia particles. As a means other than the above sublimation, the molybdenum can be removed by washing with water, an aqueous ammonia solution, an aqueous sodium hydroxide solution or the like.

At this time, the molybdenum content in the gallia particles can be controlled by appropriately changing concentration and used amount of the water, the aqueous ammonia solution, or the aqueous sodium hydroxide solution used, and a washing site, a washing time or the like.

[Pulverizing Step]

In a calcined product obtained through the calcination step, the gallia particles may aggregate, and the calcined product may not meet a range of particle diameter suitable for applications to be considered. Therefore, the gallia particles may be pulverized to satisfy the range of suitable particle diameter, if necessary.

A method for pulverizing the calcined product is not particularly limited, and conventionally known pulverizing methods such as ball mill, jaw crusher, jet mill, disc mill, Spectromill, grinder, and mixer mill can be used.

[Classification Step]

The Calcined Product Containing the Gallia Particles Obtained in the calcination step may be appropriately classified in order to adjust a range of the particle size. A “classification process” refers to an operation of grouping particles based on the size of the particles.

The classification may be either wet or dry, but from a viewpoint of productivity, the dry classification is preferable. The dry classification includes classification by sieving, wind classification by a difference between centrifugal force and fluid drag, and the like, but from a viewpoint of classification accuracy, the wind classification is preferable, and can be performed by using a classifier using Coanda effect, such as an airflow classifier, a swirling airflow classifier, a forced vortex centrifugal classifier, and a semi-free vortex centrifugal classifier.

The above-mentioned pulverizing step and classification step can be performed at a necessary stage. For example, the average particle diameter of the gallia particles to be obtained can be adjusted by the presence or absence of pulverizing and classification, and selection of their conditions.

In the gallia particles of the embodiment or the gallia particles obtained by the production method of the embodiment, the gallia particles having little or no aggregation are likely to exhibit their original properties and are superior in their own handleability, and when they are used by being dispersed in a medium to be dispersed, they are preferable from the viewpoint of being more excellent in dispersibility.

Note that according to the method for producing the gallia particles of the above-described embodiment, since the gallia particles having little or no aggregation can be easily produced, it has an excellent advantage that the gallia particles having excellent desired properties can be produced with high productivity without performing the above-mentioned pulverizing step or classification step.

### EXAMPLES

Next, the present invention will be described in more detail with reference to Examples, but the present invention is not limited to the following Examples.

<Production of Gallia Particles>

### Comparative Example 1

3.0 g of commercially available gallium oxide Ga₂O₃ (produced by Aladdin (China)) was placed in a crucible and calcined in a ceramic electric furnace at 1100° C. for 24 hours. After the temperature was lowered, the crucible was taken out to obtain 3.0 g of white powders.

### Comparative Example 2

In Comparative Example 1, 3.0 g of white powders were obtained by the same operation as in Comparative Example 1 except that a calcination condition was changed to at 1300° C. for 24 hours.

### Example 1

3.0 g of gallium oxide Ga₂O₃ (produced by Aladdin (China)) and 0.15 g of molybdenum trioxide (produced by Chengdu Hongbo Industrial Co., Ltd. (China)) were mixed in a mortar to obtain a mixture. The obtained mixture was placed in the crucible and calcined in the ceramic electric furnace at 1100° C. for 24 hours. After the temperature was lowered, the crucible was taken out to obtain 3.0 g of white powders. Subsequently, 3.0 g of the obtained white powders were suspended in 9 g of ion-exchanged water, precipitated with a centrifuge at 3000 rpm for 15 minutes, and supernatant liquid was discarded. This operation was repeated six times to wash the white powders to obtain 2.9 g of white powders.

### Examples 2 and 3

In Example 1, the powders of each Example were obtained by the same operation as in Example 1 except that a used amount of molybdenum trioxide was changed as shown in Table 1.

### Example 4

3.0 g of gallium oxide Ga₂O₃ (produced by Aladdin (China)), 2.7 g of molybdenum trioxide (produced by Chengdu Hongbo Industrial Co., Ltd. (China)), 1.3 g of potassium carbonate (produced by Aladdin (China)), and 0.015 g of yttrium oxide (produced by Aladdin (China)) were mixed in the mortar to obtain a mixture. The obtained mixture was placed in the crucible and calcined in the ceramic electric furnace at 1300° C. for 24 hours. After the temperature was lowered, the crucible was taken out to obtain 5.355 g of white powders. Subsequently, 5.355 g of the obtained white powders were suspended in 16 g of ion-exchanged water, precipitated with the centrifuge at 3000 rpm for 15 minutes, and the supernatant liquid was discarded. This operation was repeated six times to wash the white powders to obtain 3.0 g of white powders.

### Example 5

3.0 g of gallium oxide Ga₂O₃ (produced by Aladdin (China)) and 3.6 g of sodium molybdate dihydrate (produced by Aladdin (China)) were mixed in the mortar to obtain the mixture. The obtained mixture was placed in the crucible and calcined in the ceramic electric furnace at 1300° C. for 24 hours. After the temperature was lowered, the crucible was taken out to obtain 6.0 g of white solid. Subsequently, 6.0 g of the obtained white powders were suspended in 18 g of ion-exchanged water, precipitated with the centrifuge at 3000 rpm for 15 minutes, and the supernatant liquid was discarded. This operation was repeated six times to wash the white powders to obtain 2.8 g of white powders.

<Evaluation>

The washed powders obtained in Examples 1 to 5 and Comparative Examples 1 and 2 were used as sample powders and evaluated as follows.

[Crystal Structure Analysis: X-Ray Diffraction (XRD) Method]

The sample powders were filled in a holder for a measurement sample having a depth of 0.5 mm, set in a wide-angle X-ray diffraction (XRD) apparatus (Ultima IV manufactured by Rigaku Corporation), and the measurement was performed under conditions of Cu/Kα ray, 40 kV/40 mA, scanning speed 2°/min, and scanning range of 10° to 70°.

[Measurement of Particle Size Distribution]

Using a laser diffraction type dry particle size distribution meter (HELOS (H3355) & RODOS manufactured by Japan Laser Corporation), the particle size distribution of the sample powders was measured by the dry method under conditions of a dispersion pressure of 3 bar and a pulling pressure of 90 mbar. The particle diameter at a point where a distribution curve of cumulative volume % intersects a horizontal axis of 10% from the small particle side was defined as D10, the particle diameter at a point where the distribution curve intersects the horizontal axis of 50% was defined as D50, and the particle diameter at a point where the distribution curve intersects the horizontal axis of 90% from the small particle side was defined as D90, and they were determined.

[X-Ray Fluorescence (XRF) Analysis]

Using a fluorescent X-ray analyzer Primus IV (manufactured by Rigaku Corporation), about 70 mg of the sample powders were placed on a filter paper, were covered with a PP film, and the X-ray fluorescence (XRF) analysis was performed under the following conditions.

Measurement Conditions
EZ scan mode
Elements to be measured: F to U
Measurement time: standard
Measurement diameter: 10 mm
Residual (Balance component): None

The results of the Ga₂O₃ content (G₁) with respect to 100 mass % of the gallia particles and the MoO₃ content (M₁) with respect to 100 mass % of the gallia particles were obtained by XRF analysis.

[XPS Surface Analysis]

For surface element analysis of the sample powders, X-ray Photoelectron spectroscopy (XPS) measurement was performed using QUANTERA SXM manufactured by ULVAC-PHI, Inc. and monochromatic Al-Kα as an X-ray source. In an area measurement of 1000 μm square, an average value of n=3 measurement was obtained in atom % for each element.

By converting the gallium content in the surface layer and the molybdenum content in the surface layer of the gallia particles obtained by XPS analysis into oxides, the Ga₂O₃ content (G₂) (mass %) with respect to 100 mass % of the surface layer of the gallia particles and the MoO₃ content (M₂) (mass %) with respect to 100 mass % of the surface layer of the gallia particles were determined.

<Results>

Table 1 shows each value obtained by the above evaluation. Note that “N.D.” is an abbreviation for not detected, and indicates that it is not detected.

TABLE 1

| | | | | Comparative | Comparative | Example | Example | Example | Example | Example |
|---|---|---|---|---|---|---|---|---|---|---|
| | | | | Example 1 | Example 2 | 1 | 2 | 3 | 4 | 5 |
| Production | | Ga₂O₃ | g | 3 | 3 | 3 | 3 | 3 | 3 | 3 |
| Conditions | | MoO₃ | g | — | — | 0.15 | 0.6 | 3 | 2.7 | — |
| | | Na₂MoO₄•2H₂O | g | — | — | — | — | — | — | 3.6 |
| | | K₂CO₃ | g | — | — | — | — | — | 1.3 | — |
| | | Y₂O₃ | g | — | — | — | — | — | 0.015 | — |
| | | Mo/Ga | molar | — | — | 0.03 | 0.13 | 0.65 | 0.59 | 0.46 |
| | | | ratio | | | | | | | |
| | | Calcination | ° C. | 1100 | 1300 | 1100 | 1100 | 1100 | 1300 | 1300 |
| | | temperature | | | | | | | | |
| | | Calcination time | hour | 24 | 24 | 24 | 24 | 24 | 24 | 24 |
| Evaluation | Particle size | D10 | μm | 0.5 | 0.8 | 0.4 | 0.5 | 1.1 | 1.0 | 0.3 |
| | distribution | D50 | μm | 1.8 | 3.1 | 1.3 | 1.6 | 6.6 | 5.9 | 0.9 |
| | | D90 | μm | 4.3 | 6.9 | 2.6 | 4.4 | 13.0 | 15.7 | 2.2 |
| | XRF | Ga₂O₃ (G₁) | mass % | 99.8 | 99.8 | 99.6 | 98.8 | 94.5 | 75.0 | 98.4 |
| | | MoO₃ (M₁) | mass % | N.D. | N.D. | 0.1 | 0.3 | 0.2 | 8.6 | 1.3 |
| | XPS | Ga₂O₃ (G₂) | mass % | 71.1 | 71.5 | 65.1 | 55.2 | 52.5 | 16.9 | 54.5 |
| | | MoO₃ (M₂) | mass % | N.D. | N.D. | 4.4 | 5.6 | 4.8 | 33.6 | 7.2 |

| | | | | | | | |
|---|---|---|---|---|---|---|---|
| MoO₃ surface layer | — | — | 44.0 | 18.7 | 24.0 | 3.9 | 5.5 |
| uneven distribution | | | | | | | |
| ratio (M₂/M₁) | | | | | | | |

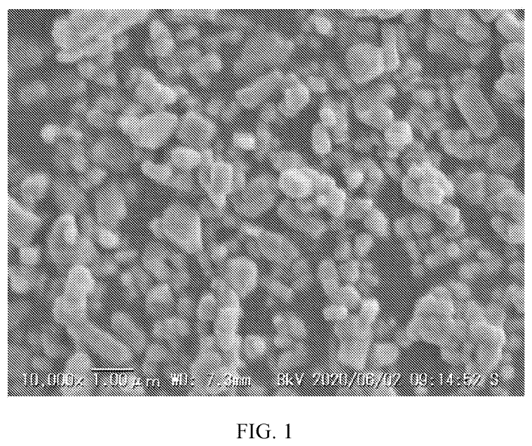

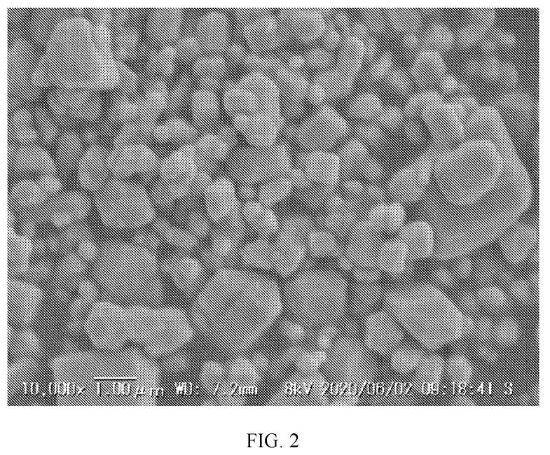

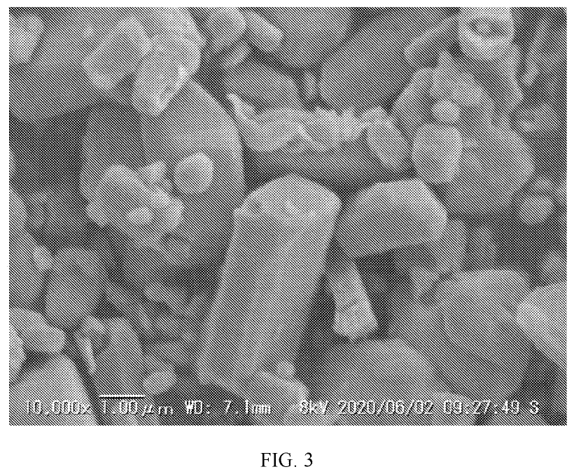

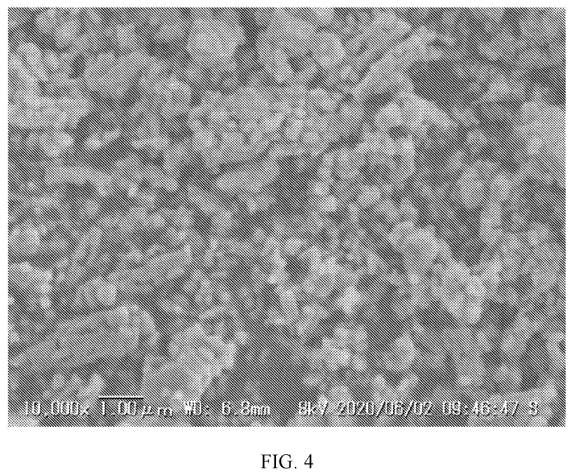

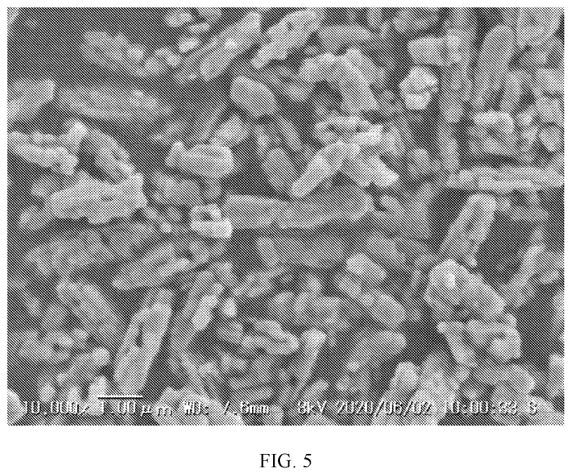

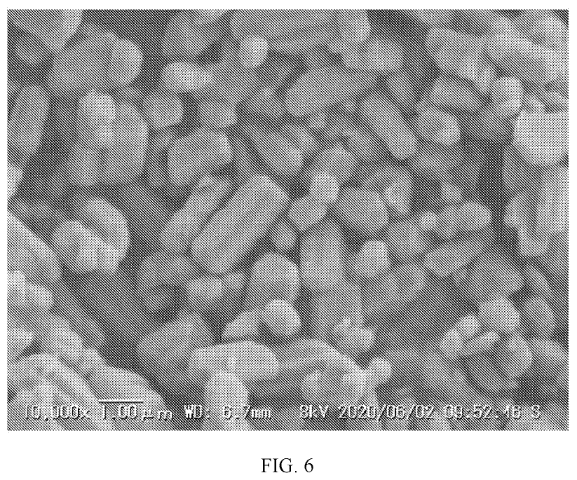

SEM images of the powders of the above Examples and Comparative Examples obtained by photographing with a scanning electron microscope (SEM) are shown in FIGS. 1 to 6. Granular or columnar particles were observed in each of Examples and Comparative Examples.

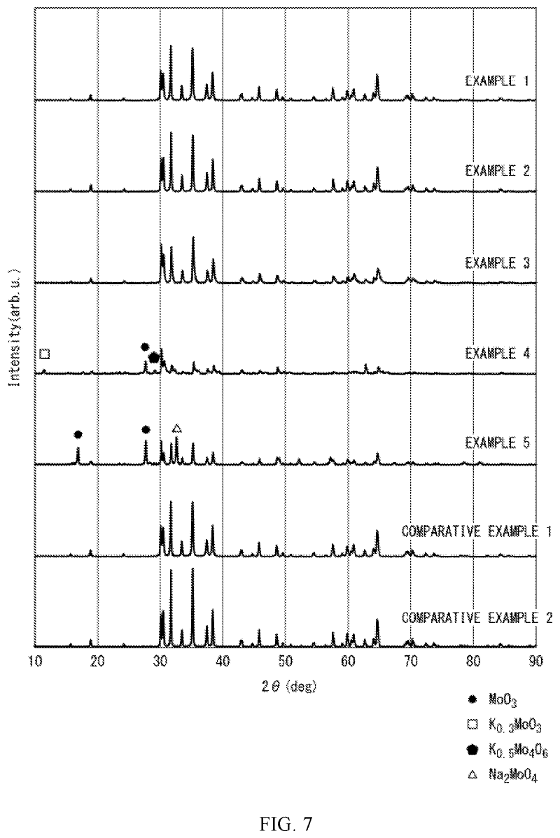

Results of XRD analysis are shown in FIG. 7. Each peak (unmarked peak) derived from the gallium oxide (Ga₂O₃) was observed in each sample of Examples and Comparative Examples.

From the results of the above SEM observation and XRD analysis, it was confirmed that the powders obtained in Examples and Comparative Examples were the gallia particles containing gallium oxide (gallia).

From the results of each Example, it was shown that it is possible to calcine the gallia particles containing molybdenum even at a relatively low calcination temperature of 1100° C. or 1300° C. by calcining the gallium compound in the presence of the molybdenum compound.

According to comparison of Examples 1 to 3, as the amount of molybdenum used is increased, the particles having a larger particle size (each value of D10, D50, D90) tend to be obtained. Therefore, it was shown that the particle size of the gallia particles to be produced can be easily controlled by calcining the gallium compound in the presence of the molybdenum compound.

Table 1 shows the values of the Ga₂O₃ content (G₁), MoO₃ content (M₁), Ga₂O₃ content (G₂), and MoO₃ content (M₂).

From the results of the MoO₃ content (M₁) and the MoO₃ content (M₂), the gallia particles of Examples 1 to 5 contain molybdenum on the surface, and it is expected that various actions of molybdenum, such as catalytic activity will be exerted.

Further, Table 1 shows calculation results of the surface layer uneven distribution ratio (M₂/M₁) of the MoO₃ content (M₂) to the MoO₃ content (M₁).

From the results of the surface layer uneven distribution ratio (M₂/M₁), in the gallia particles of Examples 1 to 5, the molybdenum oxide content in the surface layer of the gallia particles determined by XPS surface analysis is greater than the molybdenum oxide content determined by XRF analysis. Therefore, it was confirmed that molybdenum was unevenly distributed in the surface layer of the gallia particles, and it can be expected that various actions of molybdenum will be effectively exerted.

Each configuration in each embodiment, a combination thereof, and the like are examples, and the configuration can be added, omitted, replaced, and other changes can be made without departing from the spirit of the present invention. Further, the present invention is not limited by each embodiment, but is limited only by the scope of the claims.

1. Gallia particles, comprising molybdenum.

2. The gallia particles according to claim 1, wherein the molybdenum is unevenly distributed in a surface layer of the gallia particles.

3. The gallia particles according to claim 1, wherein a median diameter D₅₀ of the gallia particles calculated by a laser diffraction/scattering method is 0.1 to 1000 μm.

4. The gallia particles according to claim 1, wherein
Ga₂O₃ content (G₁) with respect to 100 mass % of the gallia particles determined by XRF analysis of the gallia particles is 65 to 99.95 mass %, and
MoO₃ content (M₁) with respect to 100 mass % of the gallia particles determined by XRF analysis of the gallia particles is 0.05 to 20 mass %.

5. The gallia particles according to claim 1, wherein
Ga₂O₃ content (G₂) with respect to 100 mass % of a surface layer of the gallia particles determined by XPS surface analysis of the gallia particles is 10 to 98 mass %, and
MoO₃ content (M₂) with respect to 100 mass % of the surface layer of the gallia particles determined by XPS surface analysis of the gallia particles is 2 to 40 mass %.

6. The gallia particles according to claim 1, wherein a surface layer uneven distribution ratio (M₂/M₁) of MoO₃ content (M₂) with respect to 100 mass % of a surface layer of the gallia particles determined by XPS surface analysis of the gallia particles to MoO₃ content (M₁) with respect to 100 mass % of the gallia particles determined by XRF analysis of the gallia particles is 2 to 80.

7. A method for producing the gallia particles, according to claim 1, comprising calcining a gallium compound in presence of a molybdenum compound.

8. The method for producing the gallia particles according to claim 7, wherein the molybdenum compound is at least one compound selected from a group including molybdenum trioxide, lithium molybdate, potassium molybdate and sodium molybdate.

9. The method for producing the gallia particles according to claim 7, wherein a calcination temperature for the calcining is 800° C. to 1600° C.
